(19) United States
(12) Patent Application Publication
(10) Pub. No.: US 2013/0011986 A1
(43) Pub. Date: Jan. 10, 2013

(54) Method for Manufacturing Full Silicide Metal Gate Bulk Silicon Multi-Gate Fin Field Effect Transistors

(76) Inventors: Huajie Zhou, Beijing (CN); Qiuxia Xu, Beijing (CN)

(21) Appl. No.: 13/321,059

(22) PCT Filed: Aug. 3, 2011
(86) PCT No.: PCT/CN11/01280

§ 371 Date: Nov. 17, 2011

(30) Foreign Application Priority Data
Jul. 8, 2011 (CN) 201110190699.9

(51) Int. Cl. H01L 21/336

(52) U.S. Cl. 438/290; 257/E21.409

(57) ABSTRACT

The present application discloses a method for manufacturing a full silicide metal gate bulk silicon multi-gate fin field effect transistor, which comprises the steps of: forming at least one fin on the semiconductor substrate; forming a gate stack structure on top and side surfaces of the fin; forming a source/drain extension area in the fin on both sides of the gate stack structure; forming a source/drain area on both sides of the source/drain extension area; forming silicide on the source/drain area; forming a full silicide metal gate electrode; and forming contact and implementing metalization. The present invention eliminates the self-heating effect and the floating body effect of SOI devices, then has a much lower cost, overcomes such defects as the polysilicon gate depletion effect, Boron penetration effect, and large series resistance of polysilicon gate electrodes, and has good compatibility with the planar COMS technology, thus it can be easily integrated.

### FIELD OF THE INVENTION

The present invention belongs to the semiconductor technical field, and particularly relates to a method for manufacturing a full silicide metal gate bulk silicon multi-gate fin field effect transistor.

### BACKGROUND OF THE INVENTION

With continuous development of the Integrated Circuitry (IC) industry under Moore' law, the feature size of CMOS device is continuously reduced, and the planar bulk silicon device with CMOS is severely challenged. To overcome such problems, solutions may be found from many aspects such as new materials, new processes, and new structures.

In the field of new materials, the technology of metal gate electrode is very important. The polysilicon gate depletion effect and Boron (B) penetration effect of a P-type field effect transistor may be thoroughly eliminated and meanwhile a very low gate sheet resistance may be acquired by using metal gate electrodes. Among various methods for manufacturing metal gates, the technology of full silicide metal gate is a relatively simple method for manufacturing metal gates, and has good compatibility with the CMOS technology.

In the field of new structures, Fin Field Effect Transistor (FinFET) structure is deemed as one of the new structure devices that is most possible to replace the planar bulk silicon CMOS device, and therefore becomes an international research hotspot. The FinFET structure is generally divided into SOI FinFET and Bulk FinFET. However, SOI FinFET has such deficiencies as high manufacture cost, poor heat dissipation, and having floating body effect and self-heating effect. In order to overcome the problems of SOI FinFET, researchers begin to study manufacture of FinFET device by using a bulk silicon substrate, i.e., Bulk FinFET.

In order to overcome the problems in the traditional planar bulk silicon device with CMOS structure and promote the IC industry to develop quickly, further researches shall be conducted in the fields of new materials, new processes and new structures, which is of far-reaching significance to the development of the semiconductor industry.

### SUMMARY OF THE INVENTION

The present invention aims to provide a new method for manufacturing a full silicide metal gate bulk silicon multi-gate fin field effect transistor, which may be easily integrated and have good compatibility with the planar CMOS technology. Such a method can overcome the problems of traditional polysilicon gate electrode materials and planar CMOS devices.

The present invention achieves the above object by following main steps of: forming at least one fin on the semiconductor substrate; forming a gate stack structure on top and side surfaces of the fin; forming a source/drain extension area in the fin on both sides of the gate stack structure; forming a source/drain area on both sides of the source/drain extension areas; forming silicide on the source/drain area; forming a full silicide metal gate electrode; and forming contact and implementing metalization.

Preferably, the step of forming at least one fin on the semiconductor substrate comprises: forming a protective dielectric layer on the semiconductor substrate; etching the protective dielectric layer and the semiconductor substrate to form at least two grooves embedded in the semiconductor substrate with one fin formed between adjacent grooves; and depositing an isolation dielectric layer on the semiconductor substrate and forming fins with the bottom thereof separated from each other by processes of Chemical Mechanical Polishing (CMP) and etching back.

Preferably, the protective dielectric layer may be formed from one of SiO₂, TEOS and Si₃N₄.

Preferably, the fin may have a width of about 10-60 nm

Preferably, the step of depositing an isolation dielectric layer on the semiconductor substrate and forming fins with the bottom thereof separated from each other by processes of CMP and etching back comprises: forming an isolation dielectric layer on the semiconductor substrate; performing CMP to the isolation dielectric layer to expose the protective dielectric layer on top of the fins; and etching back the isolation dielectric layer to expose upper parts of the fins while retaining a part of the isolation dielectric layer at bottom of the groove such that lower parts of the fins are separated from each other by the isolation dielectric layer.

Preferably, the retained part of the isolation dielectric layer may have a thickness of about 50-200 nm.

Preferably, the step of a gate stack structure on top and side surfaces of the fins comprises: forming a gate dielectric layer, a polysilicon gate electrode, and a hard mask layer on top and side surfaces of the fins; and forming a gate stack structure by photolithography and etching.

Preferably, the hard mask layer may be form from one of TEOS and Si₃N₄.

Preferably, the method of forming a source/drain extension area in the fin on both sides of the gate stack structure comprises: forming a first spacer on both sides of the fin; and performing tilt ion implantation, pre-amorphous implantation, and low-energy ion implantation, so as to form a source/drain extension area in the fin.

Preferably, the step of forming a source/drain area on both sides of the source/drain extension area comprises: forming a second spacer on both sides of the first spacer; performing source/drain ion implantation; and activating the implanted dopants to form a doped source/drain area.

Preferably, the step of forming a full silicide metal gate electrode comprises: depositing an inter-layer dielectric layer and performing CMP to the same to expose the hard mask layer on top of the polysilicon gate electrode; removing the hard mask layer on top of the polysilicon gate electrode; and converting the polysilicon gate electrode into a full silicide metal gate electrode.

Preferably, the step of converting the polysilicon gate electrode into a full silicide metal gate electrode comprises: depositing a metal layer; forming a metal silicide by reaction of most part of the polysilicon gate electrode with the metal layer using a first rapid thermal annealing; selectively removing the residual unreacted metal layer; and completely converting the polysilicon gate electrode into a metal silicide gate electrode by a second rapid thermal annealing.

Preferably, the metal layer may be formed from one of Ni, Co, Ti, W, Pt, and Ir.

Preferably, in the step of forming a metal silicide by reaction of the most part of the polysilicon gate electrode with the metal layer using a first rapid thermal annealing, most part of the polysilicon gate electrode reacts with the metal layer to form metal silicide, and a small part of the polysilicon gate electrode which is close to the gate dielectric layer does not form silicide.

Preferably, in the step of completely converting the polysilicon gate electrode into a metal silicide gate electrode by the second rapid thermal annealing, the residual part of the polysilicon gate electrode reacts with the metal layer to form silicide, so that the polysilicon gate electrode is completely converted into a metal silicide gate electrode.

In the preferred embodiments of the present invention, the semiconductor substrate is a bulk silicon substrate.

As seen from the above technical solutions, the present invention achieves the following advantageous effects:

1. A method for manufacturing a full silicide metal gate bulk silicon multi-gate fin field effect transistor is provided in the present invention, by which a fin field effect transistor device may be manufactured on the bulk silicon substrate, thus the self-heating effect and the floating body effect in the SOI FinFET device are overcome and the manufacturing cost is reduced;

2. A method for manufacturing a full silicide metal gate bulk silicon multi-gate fin field effect transistor is provided in the present invention, by which the polysilicon gate depletion effect in the polysilicon gate electrode materials and Boron (B) penetration effect of a P-type field effect transistor are overcome and meanwhile a very low gate sheet resistance is acquired;

3. A method for manufacturing a full silicide metal gate bulk silicon multi-gate fin field effect transistor is provided in the present invention, the manufacturing process thereof is feasible and easy integrated. Further, the process has good compatibility with the planar COMS technology, thus it can be easily implemented.

### BRIEF DESCRIPTION OF THE DRAWINGS

The above and other objects, features and advantages of the present invention will be more apparent through the descriptions of the embodiments with reference to the drawings below, wherein:

FIGS. 1-2, 3A-3B, 4A-4C, 5, 6A-6B, and 7-10 illustrate sectional views of the structures corresponding to the flows for manufacturing a full silicide metal gate bulk silicon multi-gate fin field effect transistor in accordance with the method in the embodiments of the present invention.

It should be noted that the drawings of the present Description are schematic and are not drawn to scale, thus they should not be construed as limiting and restricting the scope of the present invention. In the drawings, the same constituting parts are indicated by the same reference signs.

### DETAILED DESCRIPTION OF THE PREFERRED EMBODIMENTS

The present invention is described by the embodiments as illustrated in the drawings below. It should be appreciated that these descriptions are merely schematic, and do not intend to limit the scope of the invention. Furthermore, descriptions of common structures and techniques are omitted in the following description, avoiding unnecessary confusion of the concepts in the present invention.

Schematic diagrams showing layer structures according to the embodiments of the present invention are provided in the drawings. However, these diagrams are not drawn to scale, where some details may be magnified and some details may be omitted for clearness. The areas, and shapes of layers as well as relative size and positional relationships therebetween in the drawings are merely illustrative, and derivations may exist due to manufacturing tolerance or technical limitation in practice, besides areas/layers having different shapes, sizes and relative positions may be additionally designed by those skilled in the art according to practical requirement.

FIGS. 1-2, 3A-3B, 4A-4C, 5, 6A-6B and 7-10 illustrate in detail sectional views of the structures corresponding to the steps for manufacturing a full silicide metal gate bulk silicon multi-gate fin field effect transistor in accordance with embodiments of the present invention. Next, the steps in accordance with the embodiments of the present invention are described in detail with reference to these figures.

First, referring to FIG. 1, a Shallow Trench Isolation (STI) 102 is formed on a semiconductor substrate 101. Specifically, the semiconductor substrate 101 may be of substrate materials commonly used in the semiconductor manufacturing field, preferably bulk Si substrate is adopted in the embodiment of the present invention.

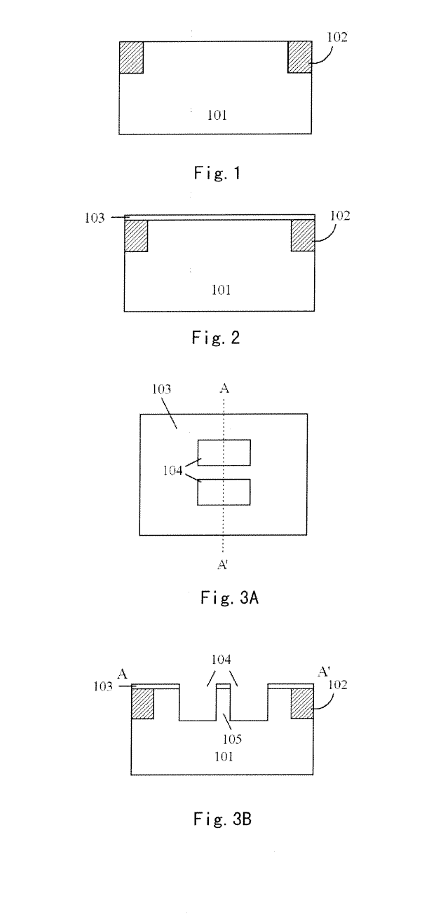

Then, as shown in FIG. 2, a protective dielectric layer 103 is formed on the semiconductor substrate 101. The protective dielectric layer 103 may include: SiO₂, TEOS, Si₃N₄ or other dielectric materials, preferably SiO₂, which may be formed via thermal growth and have a thickness of about 30-70 nm, is adopted in the embodiment of the present invention. The dielectric layer 103 may protect the at least one fin formed later effectively in the following etching process.

FIG. 3A illustrates a schematic diagram along the surface of the semiconductor substrate 101, and FIG. 3B is a sectional view in a direction AA′ in FIG. 3A. As shown in FIGS. 3A and 3B, the substrate 101 is etched so as to form at least two grooves 104 embedded in the semiconductor substrate 101. In the Figures, only two grooves are illustrated, but it may be appreciated by those ordinary skilled in the art that there may be arbitrary number of grooves. The method for forming the grooves 104 by etching may be, for example, exposing positive photoresist by electron beams and etching by reactive ions to form two adjacent steep grooves 104 having a width of about 100-400 nm*100-400 nm with a space of about 10-60 nm therebetween. The shapes of the grooves are merely illustrative, and are not limited by the present invention. A fin 105 is formed between the grooves, which may also be called as Silicon Island and may have the width selected according to practical requirement, 10-60 nm, for example.

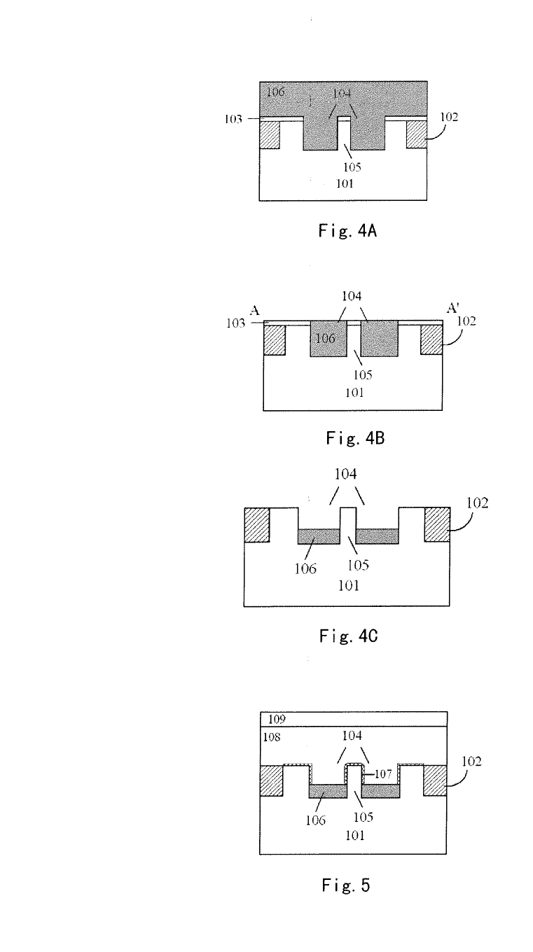

Next, as shown in FIGS. 4A, 4B and 4C, an isolation dielectric layer 106 is formed on the semiconductor substrate. Specifically, first, as shown in FIG. 4A, an isolation dielectric layer 106 is deposited on the substrate. The isolation dielectric layer 106 may be made of SiO₂, TEOS, Low Temperature Oxide (LTO) or other dielectric materials, preferably TEOS is adopted in the embodiment of the present invention, the layer may be formed by CVD and may have a thickness of about 250-500 nm. Then, as shown in FIG. 4B, the isolation dielectric layer 106 is thinned by CMP technology to the protective dielectric layer 103 on top of the fin 105. Last, as shown in FIG. 4C, the isolation dielectric layer 106 is etched back such that an upper part of the fin 105 is exposed while a part of isolation dielectric layer 106 with the thickness of about 50-200 nm is retained at the bottom of the grooves 104. The isolation layer 106 may separate the bottom of adjacent fins from each other and meanwhile can restrain turn-on of the bottom parasitic transistor, which is advantageous to decrease the leakage current and parasitic capacitance of the device and improve the performance of the device. The protective dielectric layer 103 on top of the fin 105 is removed simultaneously in the process of etching back.

Then, as shown in FIG. 5, a gate dielectric layer material 107, a polysilicon gate electrode material 108, and a hard mask 109 are formed on the entire substrate; next a gate electrode stack structure is formed by etching. The gate dielectric layer material 107 may be ordinary gate dielectric materials, for example, SiO₂ or other high-K dielectric materials such as SiON and HfAlON, HiTaON, HfSiON, Al₂O₃, preferably HfSiON is adopted in the embodiment of the present invention, which may be formed by methods of Chemical Vapor Deposition, Metal Organic Chemical Vapor Deposition or Atomic Layer Deposition etc., and the gate dielectric layer material may have a equivalent oxide layer thickness of about 5 to 50 Å. The polysilicon gate electrode material 108 may be formed by using a method of Low Pressure Chemical Vapor Deposition (LPCVD) and may be of a thickness selected from 1000 to 5000 Å. The hard mask layer 109 may be made of TEOS or Si₃N₄, and may perform the following functions: first, protecting the polysilicon gate electrode 108 from reacting with the metal layer 115 to form silicide in the following process of source and drain silicide; second, protecting the polysilicon gate electrode 108 from being destroyed in the following CMP process effectively.

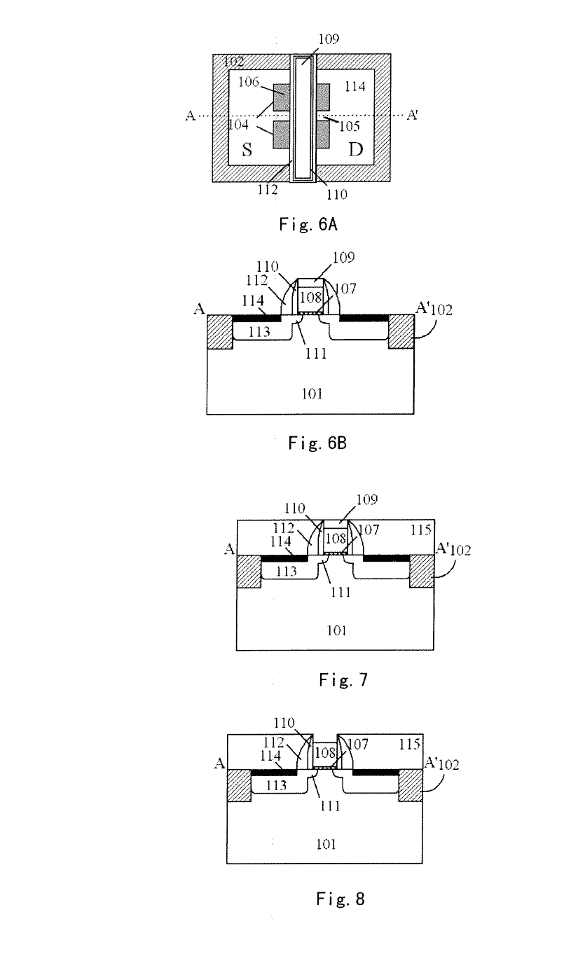

Then, as shown in FIGS. 6A and 6B, a source/drain area is formed in the semiconductor substrate on both sides of the gate stack. FIG. 6A illustrates a schematic diagram along the surface of the semiconductor substrate 101, and FIG. 6B is a sectional view in a direction AA′ in FIG. 3A. Specifically, first depositing and etching the dielectric layer to form a first spacer 110; then performing tilt angle ion implantation, pre-amorphous implantation, and low-energy ion implantation, so as to form a source/drain extension area 111 in the fin, and then depositing and etching the dielectric layer to form a second spacer 112, performing ion implantation to form a doped source/drain area 113, last forming source/drain silicide. The process for forming source/drain silicide may refer to conventional techniques, and no more unnecessary details will be provided here.

And then, as shown in FIG. 7, the interlayer dielectric layer 115 is deposited on the semiconductor substrate and performed CMP to expose the hard mask layer 109 on top of the polysilicon gate electrode 108.

Afterwards, as shown in FIG. 8, the hard mask layer 109 is removed.

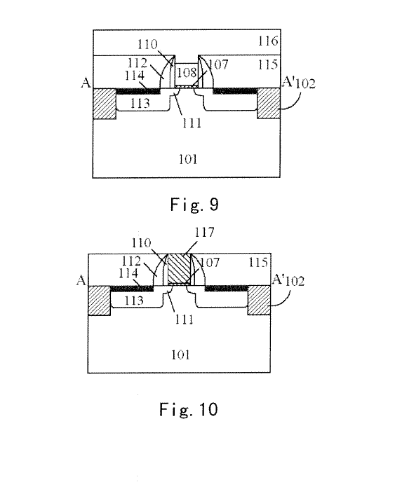

Then, as shown in FIGS. 9 and 10, a full silicide metal gate electrode is formed. Specifically, first, as shown in FIG. 9, a metal layer 116 is deposited on the semiconductor substrate. The metal layer 116 may be made of metal materials such as Ni, Co, Ti, W, Pt, and Ir. Then, as shown in FIG. 10, the polysilicon gate electrode 108 is reacted with the metal layer 116, so as to form a full silicide metal gate electrode 117. Specifically, first, most part of the polysilicon gate electrode 108 is reacted with a metal layer 116 by using a first rapid thermal annealing to form a metal silicide, leaving a small part of polysilicon gate electrode close to the gate dielectric layer not being silified, unreacted metal is then removed, and then, residual polysilicon gate electrode 108 is reacted with the metal 116 using a second rapid thermal annealing, so that polysilicon gate electrode 108 is completely converted into a metal silicide gate electrode 117.

Last, an interconnect structure is formed by metalizing so as to extract the electrode. Metalization may refer to conventional techniques, and no more unnecessary details will be provided here.

In addition, manufacture of a full silicide metal gate bulk silicon multi-gate fin field effect transistor is realized on the bulk silicon substrate through the embodiments of the present invention. The method adopts a traditional directrix plane-based top-down process, the manufacturing process is easy and feasible and has good compatibility with the planar COMS technology, and the process is easy to be integrated.

No concrete explanations are provided for the technical details of the composition and etching of all the layers in the descriptions above. However, it should be appreciated by those ordinary skilled in the art that layers and areas etc. of desired shapes may be formed through various means in the art. Furthermore, methods that are not completely the same as the above described method may also be designed by those skilled in the art, in order to form the same structure.

The present invention is illustrated with reference to the embodiments of the invention. However, these embodiments are merely illustrative, but do not intend to limit the scope of the present invention. The scope of the present invention is defined by the attached claims and the equivalents. Various substitutions and modifications may be made by those skilled in the art without departing from the scope of the invention, and such substitutions and modifications shall all fall into the scope of the present invention.

### NOTES FOR REFERENCE SIGNS

101: Si substrate; 102: STI isolation; 103: protective dielectric layer; 104: groove structure; 105: fin; 106: isolation dielectric layer; 107: gate dielectric layer; 108: polysilicon gate electrode; 109: hard mask layer; 110: first spacer; 111: source/drain extension area; 112: second spacer; 113: doped source drain area; 114: source/drain silicide; 115: interlayer dielectric layer; 116: metal layer; 117: full silicide metal gate electrode.

What is claimed is:

1. A method for manufacturing a full silicide metal gate bulk silicon multi-gate fin field effect transistor, comprising the steps of:
forming at least one fin on the semiconductor substrate;
forming a gate stack structure on top and side surfaces of the fin;
forming a source/drain extension area in the fin on both sides of the gate stack structure;
forming a source/drain area on both sides of the source/drain extension area;
forming silicide on the source/drain area;
forming a full silicide metal gate electrode; and
forming contact and implementing metalization.

2. The method according to claim 1, wherein the step of forming at least one fin on the semiconductor substrate comprises:
forming a protective dielectric layer on the semiconductor substrate;
etching the protective dielectric layer and the semiconductor substrate to form at least two grooves embedded in the semiconductor substrate with one fin formed between adjacent grooves; and
depositing an isolation dielectric layer on the semiconductor substrate, and forming fins with the bottom thereof separated from each other by processes of Chemical Mechanical Polishing (CMP) and etching back.

3. The method according to claim 2, wherein the protective dielectric layer is formed from one of SiO₂, TEOS and Si₃N₄.

4. The method according to claim 2, wherein the fin has a width of about 10-60 nm.

5. The method according to claim 2, wherein the step of depositing an isolation dielectric layer on the semiconductor substrate and forming fins with the bottom thereof separated from each other by processes of Chemical Mechanical Polishing (CMP) and etching back comprises:
forming an isolation dielectric layer on the semiconductor substrate; and
performing CMP to the isolation dielectric layer to expose the protective dielectric layer on top of the fins; and
etching back the isolation dielectric layer to expose upper parts of the fins, while retaining a part of the isolation dielectric layer at bottom of the grooves such that lower parts of the fins are separated from each other by the isolation dielectric layer.

6. The method according to claim 5, wherein the retained part of the isolation dielectric layer has a thickness of about 50-200 nm.

7. The method according to claim 1, the step of forming a gate stack structure on top and side surfaces of the fins comprises:
forming a gate dielectric layer, a polysilicon gate electrode, and a hard mask layer on top and side surfaces of the fins; and
forming a gate stack structure by photolithography and etching.

8. The method according to claim 7, the hard mask layer is formed from one of TEOS and Si₃N₄.

9. The method according to claim 1, the method of forming a source/drain extension area in the fin on both sides of the gate stack structure comprises:
forming a first spacer on both sides of the fin; and
performing tilt ion implantation, pre-amorphous implantation, and low-energy ion implantation, so as to form a source/drain extension area in the fin.

10. The method according to claim 9, the step of forming a source/drain area on both sides of the source/drain extension area comprises:
forming a second spacer on both sides of the first spacer;
performing source/drain ion implantation; and
activating the implanted dopants to form a doped source/drain area.

11. The method according to claim 7, the step of forming a full silicide metal gate electrode comprises:
depositing an inter-layer dielectric layer and performing CMP to the same to expose the hard mask layer on top of the polysilicon gate electrode;
removing the hard mask layer on top of the polysilicon gate electrode; and
converting the polysilicon gate electrode into a full silicide metal gate electrode.

12. The method according to claim 11, the step of converting the polysilicon gate electrode into a full silicide metal gate electrode comprises:
depositing a metal layer;
forming a metal silicide by reaction of most part of the polysilicon gate electrode with the metal layer using a first rapid thermal annealing;
selectively removing the residual unreacted metal layer; and
completely converting the polysilicon gate electrode into a metal silicide gate electrode by a second rapid thermal annealing.

13. The method according to claim 12, the metal layer is formed from one of Ni, Co, Ti, W, Pt, and Ir.

14. The method according to claim 12, in the step of forming a metal silicide by reaction of the most part of the polysilicon gate electrode with the metal layer using a first rapid thermal annealing, most part of the polysilicon gate electrode reacts with the metal layer to form metal silicide, and a small part of the polysilicon gate electrode which is close to the gate dielectric layer does not form silicide.

15. The method according to claim 12, in the step of completely converting the polysilicon gate electrode into a metal silicide gate electrode by the second rapid thermal annealing, the residual part of the polysilicon gate electrode reacts with the metal layer to form silicide, so that the polysilicon gate electrode is completely converted into a metal silicide gate electrode.

16. The method according to claim 1, wherein the semiconductor substrate is a bulk silicon substrate.

17. The method according to claim 2, wherein the semiconductor substrate is a bulk silicon substrate.

18. The method according to claim 5, wherein the semiconductor substrate is a bulk silicon substrate.

19. The method according to claim 11, wherein the semiconductor substrate is a bulk silicon substrate.

20. The method according to claim 12, wherein the semiconductor substrate is a bulk silicon substrate.
